(19) United States
(12) Patent Application Publication
(10) Pub. No.: US 2013/0008481 A1
(43) Pub. Date: Jan. 10, 2013

(54) ELECTRICALLY CONNECTING ELEMENT AND PHOTOVOLTAIC MODULE

(75) Inventors: Chi-Kin CHOW, Hong Kong (HK); Yang-Yang Zhou, Hong Kong (HK); Hsieh-Hsin Yeh, New Taipei City (TW)

(73) Assignee: Du Pont Apollo Limited, Hong Kong (HK)

(21) Appl. No.: 13/178,505

(22) Filed: Jul. 8, 2011

(51) Int. Cl. H01L 31/05; H01B 7/00

(52) U.S. Cl. 136/244; 174/110 R

(57) ABSTRACT

Disclosed herein is an electrically connecting element, which comprises a thin-film photovoltaic cells and an electrically connecting element disposed on a back surface of the film photovoltaic cells. The electrically connecting element comprises a conductive wire and an insulating wrapper wrapped around the conductive wire. The conductive wire has two ends and a bonding portion positioned therebetween. The insulating wrapper has a notch exposing the bonding portion. The two ends extend out of the insulating wrapper. At least one of the two ends is in contact with a bus electrode of the film photovoltaic cells, and the bonding portion is in contact with another bus electrode of the film photovoltaic cells.

### BACKGROUND

1. Field of Invention

The present invention relates to an electrically connecting element and a photovoltaic module.

2. Description of Related Art

Solar energy has gained much research attention for being a seemingly inexhaustible energy source. For such purpose, photovoltaic modules that convert solar energy directly into electrical energy are developed.

Photovoltaic modules, also known as solar modules, are devices that convert light into electricity. Solar modules provide a number of advantages when compared to conventional energy sources. For example, solar cells produce electricity without pollution and do not require any type of fossil fuels.

In general, a solar module is composed of a number of photovoltaic cells. Each of the photovoltaic cells has to be connected to another for the purpose of generating a desirable voltage and/or current. In a typical thin-film solar module structure, the photovoltaic cells are fabricated on a glass plate substrate by coating with a transparent conductivity front contact layer, a semiconductor absorber layer and a conductivity back-contact layer, respectively. Those layers are usually scribed into strips by laser or other technique during the deposition process in-between of difference layer. By overlapping the area of front and back contact layer, these strip shaped photovoltaic cells are series connected together. Electric-current is collected from the two bus-bars/electrodes that bonded on positive and negative pole which is usually located on the two outer cells, respectively. For thin-film photovoltaic cells with a multiple junctions or other high conversion efficient semiconductor (a-Si/μ-Si, CISG, CdTe, etc) structure, the module open-circuit voltage of such in series-connected cells configuration is generally in the order of 100V per m². However, a lower module voltage is always preferred in gird-connected system, as more modules can be connected in a string into an inverter with limited system voltage (600-1000V).

As we know, a thin-film photovoltaic module can be subdivided into a number of equally large sub-modules to lower the voltage. This kind of thin-film photovoltaic module consisting of multiple number (>2) of sub-modules, and sub-modules are connected in parallel via bus ribbons/electrodes to drive out the electric-power to the junction box. In such thin-film PV module lay-up, insulation materials tapes may be laid under the bus ribbons and the in-series connected cells for prevent short-circuit.

### SUMMARY

According to one aspect of the present disclosure, an electrically connecting element is provided. The electrically connecting element is applied in photovoltaic modules. The electrically connecting element comprises a conductive wire and an insulating wrapper. The conductive wire has two ends and the insulating wrapper wraps around the conductive wire. The two ends of the conductive wire extend out of the insulating wrapper. The insulating wrapper also has one or more notch(es) for exposing the bonding portions, and thus it is capable of connecting the sub-module in parallel.

According to another aspect of the present disclosure, a thin-film photovoltaic module is provided. The thin-film photovoltaic module comprises a number of equally large sub-modules and electrically connecting elements. The thin-film photovoltaic module is operable to convert light into electricity. For example, a subdivided photovoltaic module consists with five pole cells which have multiple of bus bar/electrodes bonded on the back surface. Three of the electrodes with odd number (first, third, and fifth) have the same polarity, and two of the electrodes with even number (second and fourth) have another opposite polarity. Electrically connecting elements are applied on the back it) surface for interconnecting the sub-modules in parallel. The electrically connecting elements comprise a conductive wire and an insulating wrapper. One conductive wire has two ends and a bonding portion positioned therebetween. The insulating wrapper wraps around the conductive wire. The two ends extend out of the insulating wrapper, and the insulating wrapper has a notch exposing the bonding portion. At least one of the two ends is in contact with the first electrode, and the bonding portion is in contact with the third electrode. And the other end of the conductive wire is in contact with the fifth electrode.

Another conductive wire also has two ends and a bonding portion positioned therebetween. One of the ends is contact to the fourth or second electrode, and the bonding portion is in contact with the second or fourth electrode, respectively. The other end is further connected to a junction box.

The final conductive wire only has two ends. One of the ends is contact to the first/fifth electrode, and the other end is further connected to a junction.

According to one embodiment of the present disclosure, the end in contact with the first electrode has a length of about 2 mm to about 8 mm, and the notch has a width the same as the length of the end.

According to one embodiment of the present disclosure, the end in contact with the first electrode has a length substantially the same as the other end.

According to one embodiment of the present disclosure, the end of the conductive wire has a length greater than the other end in contact with the second or fourth electrode and the notch bonding portion in contact with the fourth or second electrode, respectively.

According to one embodiment of the present disclosure, the other end of the conductive wire has a length greater than the end in contact with the first or fifth electrode.

According to one embodiment of the present disclosure, the insulating wrapper is made of polyethylene terephthalate, polyester or polyimide, and has a flat bottom surface in contact with the back surface.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a top view schematically illustrating an electrically connecting element according to one embodiment of the present disclosure;

FIG. 2 is a top view schematically illustrating an electrically connecting element according to another embodiment of the present disclosure; and

FIG. 3 is a top view schematically illustrating a photovoltaic module according to one embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

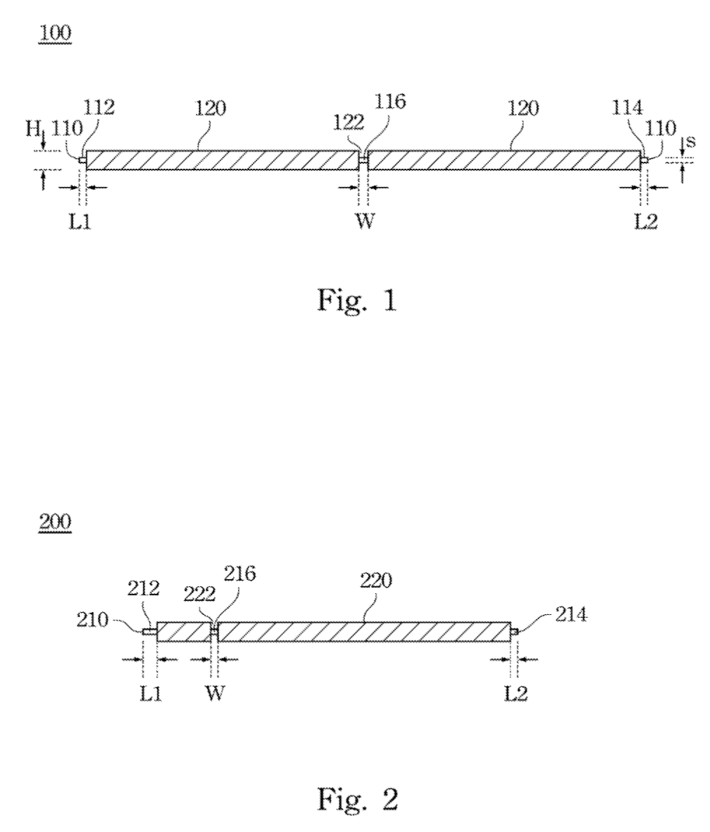

FIG. 1 is a top view schematically illustrating an electrically connecting element 100 according to one embodiment of the present disclosure. The electrically connecting element 100 may be applied in a photovoltaic module (not shown in FIG. 1). The photovoltaic module may include a plurality of solar cells and several bus electrodes. The bus electrodes are provided to collect electrical current generated by solar cells. Generally, these bus electrodes are arranged in the back surface of the photovoltaic module, and electrically connect to back electrodes of solar cells. The electrically connecting element 100 disclosed herein may be disposed on the back surface of the photovoltaic module, and connected to the bus electrodes in order to transmit electrical current from the bus electrodes to a junction box.

Referring to FIG. 1, the electrically connecting element 100 comprises a conductive wire 110 and an insulating wrapper 120. The insulating wrapper 120 substantially wraps around the conductive wire 110. In examples, the electrically connecting element 100 may be configured in a shape of a stripe or ribbon.

The conductive wire 110 has two ends 112, 114 and a bonding portion 116 positioned between the two ends 112, 114. The two ends 112, 114 extend out of the insulating wrapper 120, and respectively have lengths of L1, L2. At least one of the two ends 112, 114 may be adapted to connect to a bus electrode of the photovoltaic module. The conductive wire 110 may be made of copper, silver, gold, aluminum or other metals. In one example, the conductive wire 110 may have a diameter or width of about 2 mm to about 8 mm.

In one example, the electrically connecting element 100 has a symmetric structure. The bonding portion 116 may be located at the center position of the conductive wire 110, as depicted in FIG. 1. The length L1 of the end 112 equals the length L2 of the end 114. In this example, the two ends 112, 114 are used for connecting to bus electrodes of a photovoltaic module. The lengths L1, L2 may be selected in the range of, for example, 2 mm to 8 mm to provide a desirable bonding to the bus electrode.

The insulating wrapper 120 has a notch 122, and thus allowing the bonding portion 116 of the conductive wire 110 to be exposed. It is noted that the width W of the notch 122 is equal to the length of the bonding portion 116. The bonding portion 116 is operable to bond with a bus electrode, and may have a length the same as the end 112 or the end 114. In examples, the width W of the notch 122 may be in the range of about 2 mm to about 8 mm, for example 4 mm. The insulating wrapper 120 may be made of insulating material such as polyethylene terephthalate (PET), polyester or polyimide.

In one example, the insulating wrapper 120 has a flat bottom surface for contact with the back surface of the photovoltaic module. The width of the insulating wrapper 120 may be about twice of the width of the conductive wire 110. For example, the width H of the insulating wrapper 120 may be about 10 mm and the width S of the conductive wire is about 5 mm.

FIG. 2 is a top view schematically illustrating an electrically connecting element 200 according to another embodiment of the present disclosure. The electrically connecting element 200 has an asymmetric structure. The electrically connecting element 200 comprises a conductive wire 210 and an insulating wrapper 220. The insulating wrapper 220 substantially wraps around the conductive wire 210.

The conductive wire 210 has two ends 212, 214 and a bonding portion 216 positioned between the two ends 212, 214. The two ends 212, 214 extend out of the insulating wrapper 220, and respectively have lengths of L1, L2. In this embodiment, the end 214 is used for connecting to a bus electrode of a photovoltaic module whereas the end 212 is used for connecting to a junction box. The length L1 of the end 212 for connecting to a junction box is greater than the length L2 of the end 114. Specifically, the length L1 may be about 2 mm to about 40 mm, for example 31 mm, and the length L2 may be about 2 mm to about 8 mm, for example 4 mm. In this example, the bonding portion 216 is not located at the center of the conductive wire 110.

The insulating wrapper 220 may have the same features as those described above in connection with FIG. 1. In particular, the insulating wrapper 220 has a notch 222 to expose the bonding portion 216.

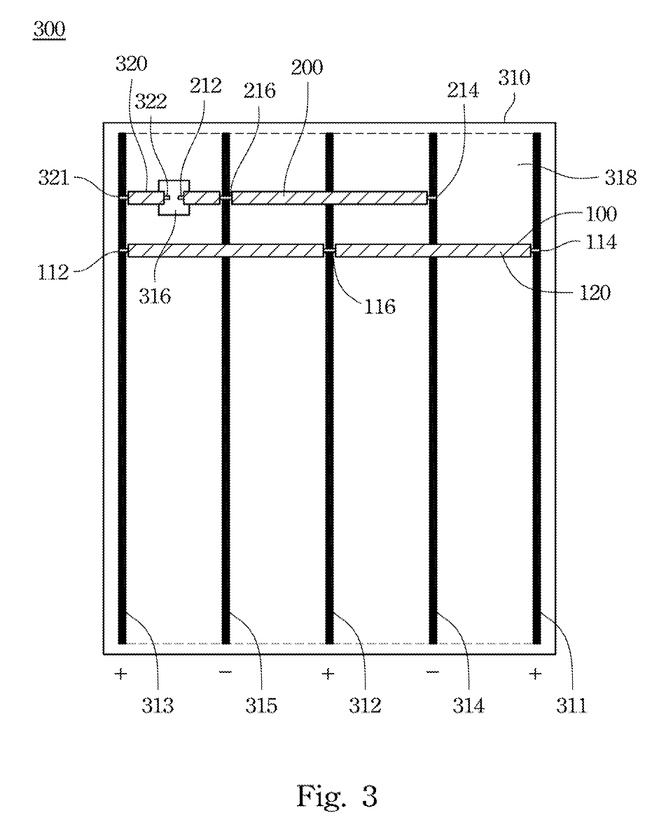

According to another aspect of the present disclosure, a photovoltaic module is provided. FIG. 3 is a top view schematically illustrating a photovoltaic module 300 according to one embodiment of the present disclosure. The photovoltaic module 300 includes a number of thin-film photovoltaic cells 310, and a first electrically connecting element 100 disposed on the back surface 318 of the thin-film photovoltaic cells 310.

The thin-film photovoltaic cells 310 are capable of converting light into electricity. The thin-film photovoltaic cells 310 have a first bus electrode 311 and a third bus electrode 312 positioned on the back surface 318. The bus electrodes 311, 312 may have the same length and extend in parallel, and are operable to collect electric current generated by the thin-film photovoltaic cells 310. Furthermore, both the first and third bus electrodes 311, 312 have the same polarity. For example, both the first and third bus electrodes 311, 312 are positive electrodes of the thin-film photovoltaic cells 310.

The first electrically connecting element 100 may have a structure similar to those described above in connection with FIG. 1. The first electrically connecting element 100 comprises a conductive wire 110 and an insulating wrapper 120, which wraps around the conductive wire 110. The conductive wire 110 has a first end 114 and a bonding portion 116 respectively in contact with the first electrode 311 and the third electrode 312. Specifically, conductive pastes or solders may be employed to bond the first end 114 and the bonding portion 116 respectively with the first bus electrode 311 and the third bus electrode 312.

In one embodiment, the thin-film photovoltaic cells 310 further comprise a fifth electrode 313 disposed on the back surface 318. The polarity of the fifth bus electrode 313 is the same as the first bus electrode 311. Further, the conductive wire 110 has a second end 112 in contact with the fifth bus electrode 313, as depicted in FIG. 3. In this embodiment, both the bonding portion 116 and the notch 122 locate at a center position of the first electrically connecting element 100. Moreover, each of the first and second ends 114, 112 may have a length substantially the same as the length of the bonding portion 116. In examples, each of the first and second ends 114, 112 and the bonding portion 116 may have a length of about 2 mm to about 8 mm, specifically about 4 mm.

In another embodiment, the photovoltaic module 300 further includes a second electrically connecting element 200. In this embodiment, the thin-film photovoltaic cells 310 further comprises a second bus electrode 314, a fourth bus electrode 315 and a junction pad 316 disposed on the back surface 318. Both the second and the fourth bus electrode 314, 315 have the same polarity, which is opposite to the polarity of the first bus electrode 311. The junction pad 316 is made of an insulating material, and a junction box (not shown) may be arranged on the junction pad 316. The second electrically connecting element 200 have a structure similar to those described above in connection with FIG. 2.

The second electrically connecting element 200 comprises a conductive wire 210 and an insulating wrapper 220 (as shown in FIG. 2). The conductive wire 210 has a first end 214, a second end 212 and a bonding portion 216. The first ends 214 is in contact with the second bus electrode 314 whereas the second end 212 is positioned on the junction pad 316, and may be further connected to the junction box. Further, the bonding portion 216 is in contact with the fourth bus electrode 315.

In still another embodiment, the photovoltaic module 300 may further comprise a conductive wire 320. The conductive wire 320 may have a structure substantially the same as the first or the second electrically connecting element 100, 200, except that there is no notch appeared on the insulating wrapper. In other words, the conductive wire 320 has two ends 321, 322 extending out of the insulating wrapper, but is not provided with a bonding portion. The end 321 is bonded with the fifth bus electrode 313. The other end 322 is positioned on the junction pad 316, and is further connected to the junction box. The electric current generated by the thin-film photovoltaic cells 310 is firstly collected by the bus electrodes, and then is collected to the junction box through the in-parallel connection by the first and the second electrically connecting elements 100, 200 and the conductive wire 320. The first and the second electrically connecting elements 100, 200 are wrapped by insulating material, so that the connecting elements 100, 200 may cut across the bus electrodes that have different polarity and prevent of short circuit.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electrically connecting element for a photovoltaic module, the electrically connecting element comprising:
a conductive wire having two ends and a bonding portion positioned therebetween; and
an insulating wrapper wrapped around the conductive wire, wherein the two ends extends out of the insulating wrapper, and the insulating wrapper has a notch exposing the bonding portion so that the bonding portion is capable of being connected to an electrode of the photovoltaic module.

2. An electrically connecting element for a photovoltaic module, the electrically connecting element comprising:
a conductive wire having two ends and a plurality of bonding portions positioned therebetween; and
an insulating wrapper wrapped around the conductive wire, wherein the two ends extends out of the insulating wrapper, and the insulating wrapper has a plurality of notches exposing the bonding portions so that the bonding portions are capable of being connected to electrodes of the photovoltaic module.

3. A photovoltaic module, comprising:
a thin-film photovoltaic element having a first electrode and a third electrode positioned on a back surface thereof, the first and third electrodes having the same polarity; and
an electrically connecting element disposed on the back surface, comprising:
a conductive wire having two ends and a bonding portion positioned therebetween; and
an insulating wrapper wrapped around the conductive wire, wherein the two ends extend out of the insulating wrapper, and the insulating wrapper has a notch exposing the bonding portion;
wherein at least one of the two ends is in contact with the first electrode, and the bonding portion is in contact with the third electrode.

4. The photovoltaic module according to claim 3, wherein the photovoltaic cells further comprises a fifth electrode having the same polarity as the first electrode, and the other end of the conductive wire is in contact with the third electrode.

5. The photovoltaic module according to claim 4, wherein the bonding portion substantially is located at a center position of the conductive wire.

6. The photovoltaic module according to claim 5, wherein the notch substantially is located at a center position of the insulating wrapper.

7. The photovoltaic module according to claim 3, wherein the end of the conductive wire, in contact with the first electrode, has a length of about 2 mm to about 8 mm.

8. The photovoltaic module according to claim 7, wherein the notch and the end of the conductive wire, in contact with the first electrode, are of equal-length.

9. The photovoltaic module according to claim 3, wherein the end of the conductive wire, in contact with the first electrode, has a length substantially the same as the other end.

10. The photovoltaic module according to claim 3, wherein the end of the conductive wire has a length greater than the other end in contact with the second electrode and the notch bonding portion in contact with the fourth electrode.

11. The photovoltaic module according to claim 3, wherein the insulating wrapper is made of polyethylene terephthalate, polyester or polyimide, and has a flat bottom surface in contact with the back surface.
